(19) United States
(12) Patent Application Publication
(10) Pub. No.: US 2010/0134962 A1
(43) Pub. Date: Jun. 3, 2010

(54) SLIDE MECHANISM AND SLIDE-TYPE PORTABLE ELECTRONIC DEVICE USING THE SAME

(75) Inventor: HUNG-CHEN WU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/511,140

(22) Filed: Jul. 29, 2009

(30) Foreign Application Priority Data
Nov. 28, 2008 (CN) 200810305853.0

(51) Int. Cl. H05K 7/00; F16C 29/02

(52) U.S. Cl. 361/679.01; 384/10

(57) ABSTRACT

A slide mechanism includes a rear cover, and a front cover slidably attached to the rear cover. One of the rear cover and the front cover defines two sliding grooves, the other forms two sliding rails slidably engaged in the sliding grooves. An elastic portion is formed on one of the rear cover and the front cover, and abuts against the other of the rear cover and the front cover, thereby enabling the sliding rails to tightly contact with said surfaces of the sliding grooves.

### BACKGROUND

1. Technical Field

The present disclosure generally relates to portable electronic devices and, particularly to a slide-type portable electronic device and a slide mechanism used for the slide-type portable electronic device.

2. Description of Related Art

Slide-type portable electronic devices, for example slide-type mobile phones are popular. The slide-type portable electronic device includes a main body, and a display cover slidably connected on the main body via a slide mechanism, thereby opening or closing the portable electronic device.

A commonly used slide mechanism includes a rear cover mounted on the main body, and a front cover mounted on the display cover. The front cover forms two sliding rails on opposite sides. The rear cover defines two sliding grooves in opposite sides. The sliding rails are slidably engaged in the sliding grooves, thus enabling the front cover to slide relative to the rear cover.

However, the sliding rails and the sliding grooves are generally shaped by stamping, thereby the machining precision is poor, resulting that a gap between the slide rail and a side surface of the corresponding sliding groove may be larger than desired. As a result, during the sliding process, the front cover does not stably slide relative to the rear cover due to the gap. The display cover may wobble during opening/closing of the portable electronic device.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views, and all the views are schematic

FIG. 1 is an assembled, isometric view of an exemplary embodiment of a slide-type portable electronic device.

FIG. 2 is an exploded, isometric view of the slide-type portable electronic device in FIG. 1.

FIG. 3 is a cross-section of the slide-type portable electronic device in FIG. 1, taken along line III-III.

### DETAILED DESCRIPTION

The slide-type portable electronic device may be a mobile phone, a personal digital assistant, or a media player. Hereinafter, for the purposes of conveniently describing the slide-type portable electronic device, an exemplary embodiment of a slide-type mobile phone is described and illustrated.

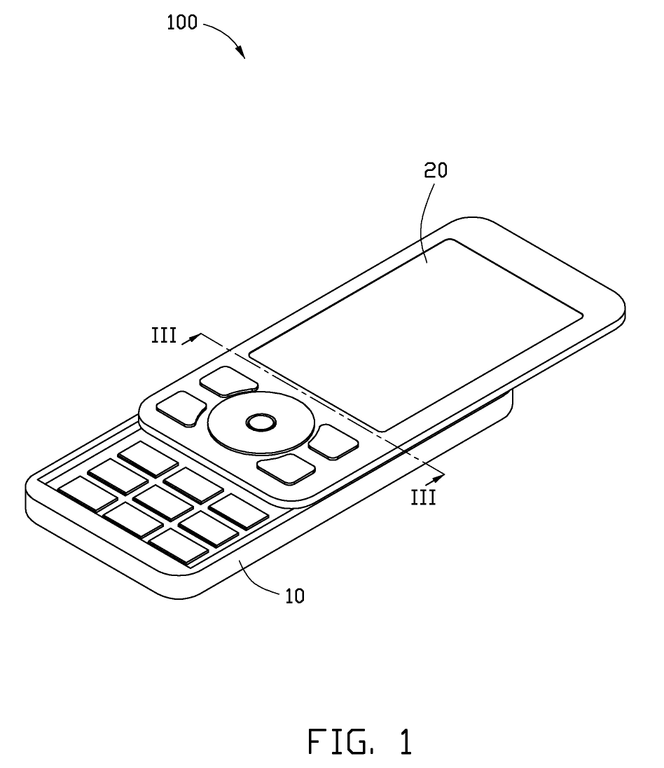

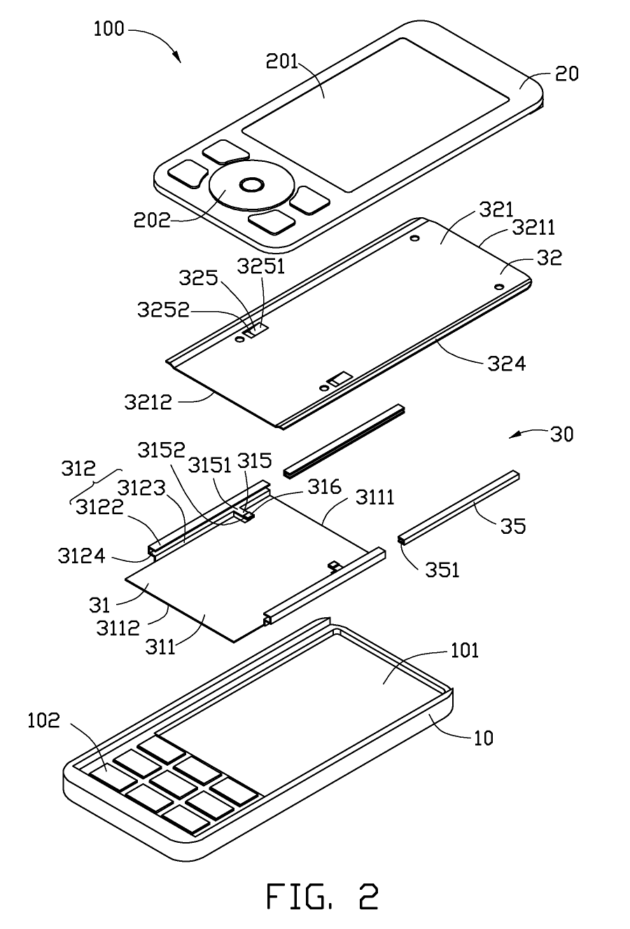

Referring to FIGS. 1 and 2, a slide-type portable electronic device 100 includes a main body 10, a display cover 20, and a slide mechanism 30. The display cover 20 is slidably assembled on the main body 10 via the slide mechanism 30.

The main body 10 defines a cavity 101, and includes a plurality of pressing keys 102 positioned on an end of the main body 10 adjacent to the cavity 101.

The display cover 20 includes a screen 201 positioned on the cover 20, and a plurality of function keys 202 positioned on an end of the cover 20 adjacent to the screen 201.

The slide mechanism 30 includes a rear cover 31 positioned on the cavity 101 of the main body 10, a front cover 32 mounted on the display cover 20, and two guiding rails 35.

The rear cover 31 includes a main plate 311, and two shoulders 312 extending from opposite sides of the main plate 311. The main plate 311 is a substantially rectangular sheet, and has a first end 3111 and a second end 3112 opposite to the first end 3111. Each shoulder 312 includes a sliding portion 3122, and a connecting portion 3123 connecting the sliding portion 3122 to the main plate 311. The two sliding portions 3122 are positioned parallel to each other. A cross-section of each sliding portion 3122 taken along a height direction is substantially C-shaped, and each sliding portion 3122 defines a sliding groove 3124. Two elastic portions 315 are symmetrically formed on opposite sides of the main plate 311 adjacent to the first end 3111. In the illustrated embodiment, the elastic portions 315 are elastic tabs formed on the shoulders 312. A first end 3151 of each elastic portion 315 is fixed on the connecting portion 3123, a second, free end 3152 of each elastic portion 315 is arranged over the main plate 311. The second end 3152 of the elastic portion 315 can move downwards towards the main plate 311 when pressed by an external force. A frictional pad 316 is positioned on the second end 3152 of each elastic portion 315. The frictional pad 316 may be made of elastic materials, such as rubber, polyformaldehyde (POM) and etc.

The front cover 32 is a substantially rectangular sheet having a main plate 321 and two sliding rails 324 formed at opposite sides of the main plate 321. The sliding rails 324 extend along the sides of the main plate 321 correspondingly. The main plate 321 has a first end 3211, and a second end 3212 opposite to the first end 3211. Two resisting portions 325 are formed on the main plate 321 corresponding to the elastic portions 315 of the rear cover 31. In the illustrated embodiment, the resisting portions 325 are elastic pieces symmetrically formed on the main plate 321 adjacent to the second end 3212. A first end 3251 of each resisting portion 325 is connected on the main plate 321, a second, free end 3252 of each resisting portion 325 is bent towards a bottom surface of the main plate 321. The second end 3252 of the resisting portion 325 can move upwards when pushed by an external force.

Each guiding rail 35 is substantially an elongated bar, and configured to be received in the sliding groove 3124 of the rear cover 31. Each guiding rail 35 defines a guiding groove 351. The guiding rail 35 may be made of elastic materials having a low friction coefficient, such as POM.

When assembling the slide-type portable electronic device 100, the rear cover 31 is fixed in the cavity 101 of the main body 10. The guiding rails 35 are fixed in the sliding grooves 3124 of the rear cover 31. The front cover 32 is mounted on the display cover 20, and the sliding rails 324 of the front cover 32 are slidably engaged in the guiding grooves 351 of the guiding rails 35. Thus, the display cover 20 is slidably connected on the main body 10.

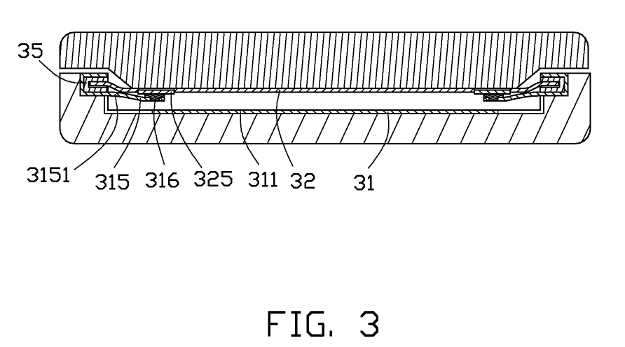

Referring also to FIG. 3, to open the slide-type portable electronic device 100, an external force is applied to push the display cover 20. The front cover 32 slides relative to the rear cover 31 along a direction from the second end 3112 to the first end 3111 of the rear cover 31, until the pressing keys 102 of the main body 10 are fully exposed. During the sliding process, the elastic portions 315 of the rear cover 31 are pressed by the front cover 32, the elastic portions 315 produce elastic forces to abut against the front cover 32, thereby enabling the sliding rails 324 to tightly contact with the guiding rails 35. Therefore, the front cover 32 slides stably relative to the rear cover 31. When the front cover 32 slides near to the opened state, the resisting portions 325 contact the elastic portions 315, the resisting portions 325 and the elastic portions 315 are both deformed elastically, and produce retarding forces therebetween. In the opened state, the retarding forces between the elastic portions 315 and the resisting portions 325 are maximized, so that the front cover 32 is stably retained in the opened state.

To close the slide-type portable electronic device 100, an external force is applied to push the display cover 20. The front cover 32 slides relative to the rear cover 31 along a direction from the first end 3111 to the second end 3112 of the rear cover 31, until the main body 10 is fully covered by the display cover 20. During the sliding process, after the resisting portions 325 separate from the elastic portions 315, a small external force is needed to slide the front cover 32. The elastic portions 315 abut against the front cover 32, thereby enabling the sliding rails 324 to tightly contact with the guiding rails 35. Therefore, the front cover 32 slides stably relative to the rear cover 31.

In the above slide-type portable electronic device 100, the guiding rails 35 are fixed in the sliding grooves 3124 of the rear cover 31 to reduce the gaps between the sliding rails 324 and the side surfaces of the sliding grooves 3124. The elastic portions 315 are positioned on the rear cover 31 to abut against the front cover 32, thereby enabling the sliding rails 324 to tightly contact with the guiding rails 35. Therefore, the front cover 32 slides stably relative to the rear cover 31, prevent wobbling from occurring between the display cover 20 and the main body 10. Additionally, the frictional pads 316 are configured on the elastic portions 315 to protect the elastic portions 315 and the front cover 32 from abrasion.

In alternative embodiments, the elastic portions 315 may be formed on front cover 32, the resisting portions 325 may be formed on rear cover 31. The number of the elastic portion 315 and the resisting portion 325 may be one or more. The sliding grooves 3124 may be defined in the front cover 32, the sliding rails 324 may be formed on the rear cover 31. If the gaps between the sliding rail 324 and the side surfaces of the sliding grooves 3124 are not too large, the guiding rails 35 may be omitted.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A slide mechanism comprising:
a rear cover;
a front cover slidably attached to the rear cover, one of the rear cover and the front cover defining two sliding grooves, and the other forming two sliding rails slidably engaged in the sliding grooves; and
an elastic portion formed on one of the rear cover and the front cover, the elastic portion abutting against the other of the rear cover and the front cover, thereby enabling the sliding rails to tightly contact with said surfaces of the sliding grooves.

2. The slide mechanism of claim 1, wherein the rear cover comprises a main plate, and two sliding portions formed on opposite sides of the main plate of the rear cover, the sliding grooves are defined in the sliding portions; and the front cover also comprises a main plate, the sliding rails are formed on opposite sides of the main plate of the front cover.

3. The slide mechanism of claim 2, wherein the rear cover further comprises two connecting portions connecting the sliding portions on the main plate of the rear cover; and the elastic portion is an elastic tab formed on the rear cover, a first end of the elastic portion is fixed on the connecting portion, a second end of the elastic portion is arranged over the main plate of the rear cover.

4. The slide mechanism of claim 1, further comprising a frictional pad positioned on the elastic portion.

5. The slide mechanism of claim 1, further comprising a resisting portion formed on the other of the rear cover and the front cover, the elastic portion contacts with the resisting portion, thereby retaining the slide mechanism in the opened state.

6. The slide mechanism of claim 5, wherein the resisting portion is an elastic piece formed on the front cover, a first end of the resisting portion is connected on the front cover, a second end of the resisting portion is bent towards the bottom surface of the front cover.

7. A slide mechanism comprising:
a rear cover;
a front cover slidably attached to the rear cover, one of the rear cover and the front cover defining two sliding grooves, the other forming two sliding rails;
two guiding rails respectively fixed in the sliding grooves, each guiding rail defining a guiding groove, the sliding rails being slidably engaged in the guiding grooves; and
an elastic portion formed on one of the rear cover and the front cover, the elastic portion abutting against the other of the rear cover and the front cover, thereby enabling the sliding rails to tightly contact with the guiding rails.

8. The slide mechanism of claim 7, wherein the rear cover comprises a main plate, and two sliding portions formed on opposite sides of the main plate of the rear cover, the sliding grooves are defined in the sliding portions; and the front cover also comprises a main plate, the sliding rails are formed on opposite sides of the main plate of the front cover.

9. The slide mechanism of claim 8, wherein the rear cover further comprises two connecting portions connecting the sliding portions on the main plate of the rear cover; and the elastic portion is an elastic tab formed on the rear cover, a first end of the elastic portion is fixed on the connecting portion, a second end of the elastic portion is arranged over the main plate of the rear cover.

10. The slide mechanism of claim 7, further comprising a frictional pad positioned on the elastic portion.

11. The slide mechanism of claim 7, further comprising a resisting portion formed on the other of the rear cover and the front cover, the elastic portion contacts with the resisting portion, thereby retaining the slide mechanism in the opened state.

12. The slide mechanism of claim 11, wherein the resisting portion is an elastic piece formed on the front cover, a first end of the resisting portion is connected on the front cover, and a second end of the resisting portion is bent towards the bottom surface of the front cover.

13. The slide mechanism of claim 7, wherein the guiding rails are made of elastic materials having a low friction coefficient.

14. A slide type portable electronic device comprising:
a main body;
a display cover; and
a slide mechanism slidably connecting the display cover on the main body, the slide mechanism comprising:
a rear cover mounted on the main body;
a front cover mounted on the display cover, one of the rear cover and the front cover defining two sliding grooves, the other forming two sliding rails slidably engaged in the sliding grooves; and
an elastic portion formed on one of the rear cover and the front cover, the elastic portion abutting against the other of the rear cover and the front cover, thereby enabling the sliding rails to tightly contact with said surfaces of the sliding grooves.

15. The slide type portable electronic device of claim 14, wherein the rear cover comprises a main plate, and two sliding portions formed on opposite sides of the main plate of the rear cover, the sliding grooves are defined in the sliding portions; and the front cover also comprises a main plate, the sliding rails are formed on opposite sides of the main plate of the front cover.

16. The slide type portable electronic device of claim 15, wherein the rear cover further comprises two connecting portions connecting the sliding portions on the main plate of the rear cover; and the elastic portion is an elastic tab formed on the rear cover, a first end of the elastic portion is fixed on the connecting portion, a second end of the elastic portion is arranged over the main plate of the rear cover.

17. The slide type portable electronic device of claim 14, further comprising a frictional pad positioned on the elastic portion.

18. The slide type portable electronic device of claim 14, further comprising a resisting portion formed on the other of the rear cover and the front cover, the elastic portion contacts with the resisting portion, thereby retaining the slide mechanism in the opened state.

19. The slide type portable electronic device of claim 18, wherein the resisting portion is an elastic piece formed on the front cover, a first end of the resisting portion is connected on the front cover, a second end of the resisting portion is bent towards the bottom surface of the front cover.

20. The slide type portable electronic device of claim 14, wherein the main body defines a cavity, the rear cover is fixed in the cavity of the main body.
